(19) United States
(12) Patent Application Publication
(10) Pub. No.: US 2014/0353895 A1
(43) Pub. Date: Dec. 4, 2014

(54) CARRYING APPARATUS

(71) Applicants: HONG FU JIN PRECISION INDUSTRY (ShenZhen) CO., LTD ., Shenzhen (CN); HON HAI PRECISION INDUSTRY CO., LTD., New Taipei (TW)

(72) Inventor: TAO ZHAO, Shenzhen (CN)

(73) Assignees: HONG FU JIN PRECISION INDUSTRY (ShenZhen) CO., LTD ., Shenzhen (CN); HON HAI PRECISION INDUSTRY CO., LTD., New Taipei (TW)

(21) Appl. No.: 14/287,647

(22) Filed: May 27, 2014

(30) Foreign Application Priority Data
May 30, 2013 (CN) 2013102088101

(51) Int. Cl. H05K 3/30

(52) U.S. Cl. CPC H05K 3/301; H05K 2203/0165
USPC 269/55

(57) ABSTRACT

A carrying apparatus is fixed on a base for carrying a printed circuit board (PCB). The carrying apparatus comprises a carrying mechanism for receiving the PCB and a positioning mechanism mounted on the base. The carrying mechanism is received in the positioning mechanism and is capable of detaching from the positioning mechanism.

### FIELD

The present disclosure relates to carrying apparatuses.

### BACKGROUND

An apparatus is provided for supporting a printed circuit board (PCB) on a solder device while soldering electronic components on the PCB. Each apparatus can only receive the PCB with the same size.

### BRIEF DESCRIPTION OF THE FIGURE

The components of the drawings are not necessarily drawn to scale, the emphasis instead being placed upon clearly illustrating the principles of the embodiment of a carrying apparatus. Like reference numerals designate corresponding parts throughout several views.

FIG. 1 is a schematic view of a carrying apparatus, according to an embodiment.

FIG. 2 is a schematic view of the carrying apparatus of FIG. 1 being opened.

FIG. 3 is a partially disassembled view of the apparatus of FIG. 1.

FIG. 4 is similar to FIG. 3, but viewed from another aspect.

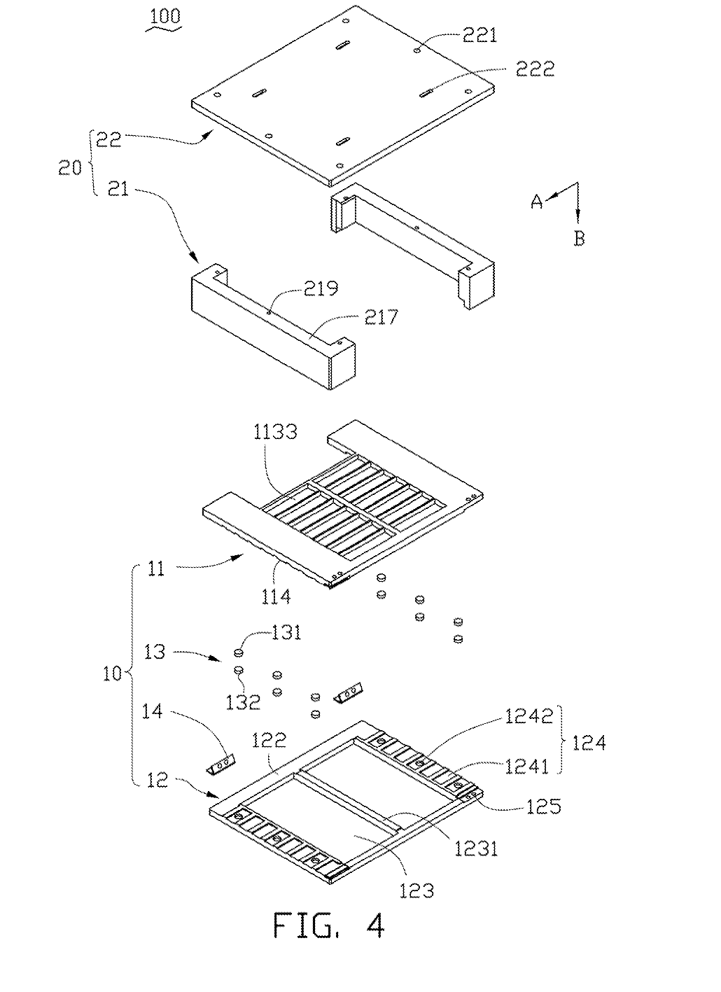

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.” Embodiments of the present disclosure will be described in detail with reference to the drawings.

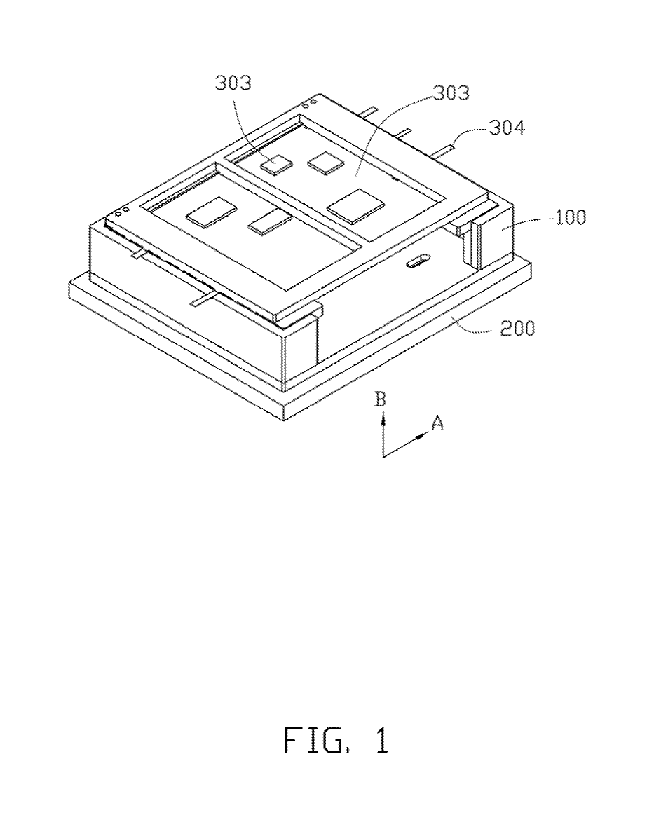

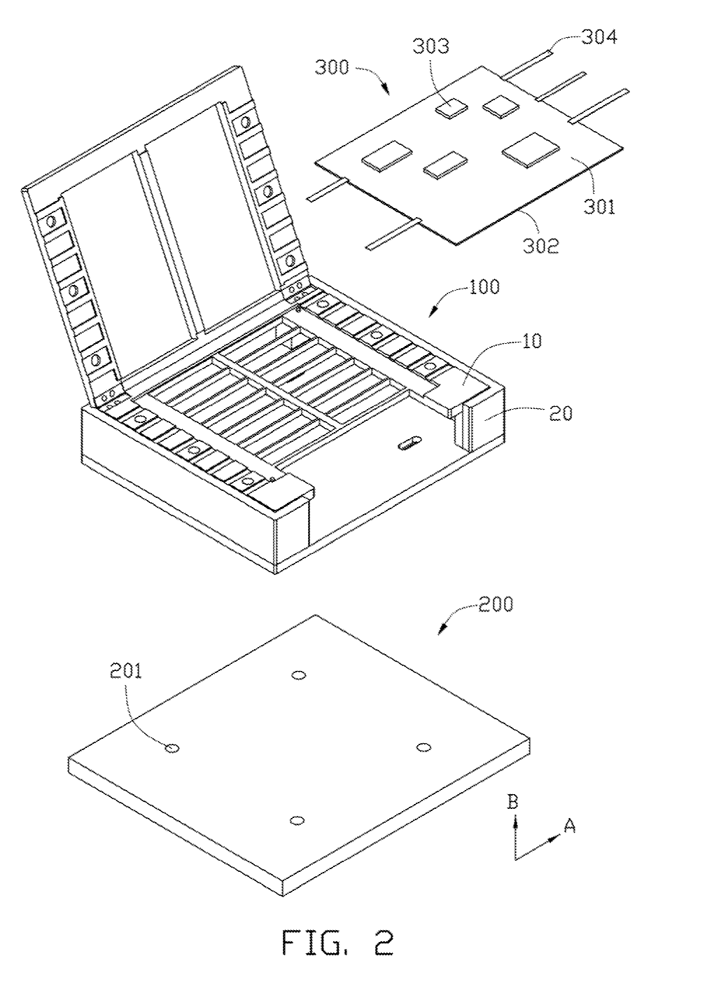

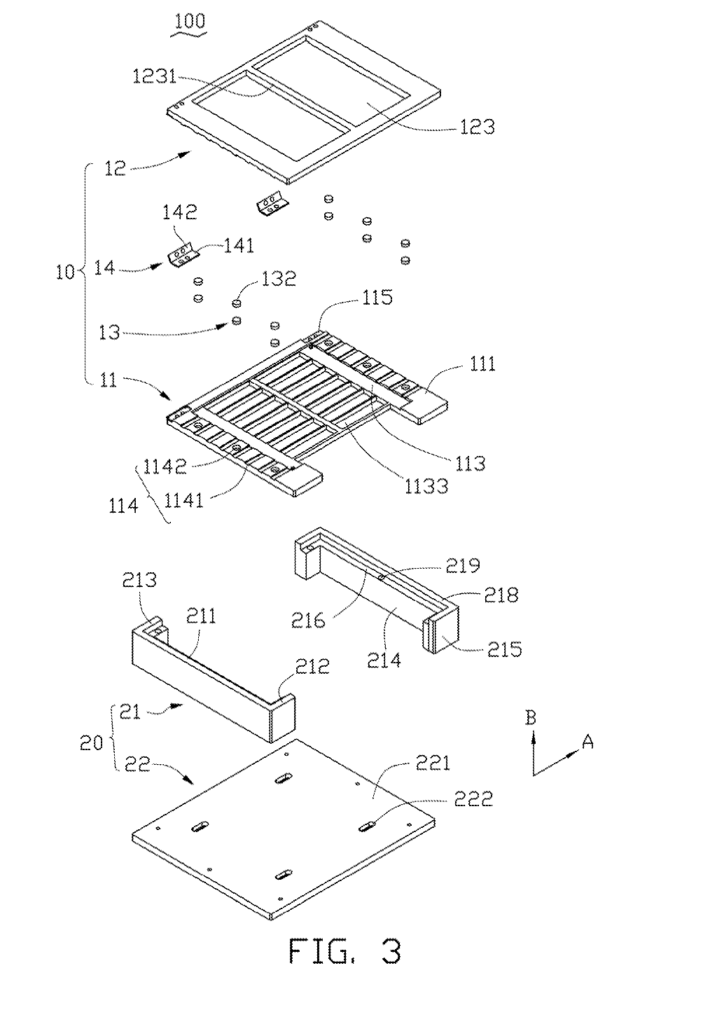

FIGS. 1-3 illustrate a carrying apparatus 100 of the embodiment. The carrying apparatus 100 is mounted on a base 200 for carrying different printed circuit boards (PCBs) 300 while soldering electronic component 303 on the PCBs 300

The carrying apparatus 100 includes a carrying mechanism 10 and a positioning mechanism 20. The carrying mechanism 10 is mounted on the positioning mechanism 20 for loading the PCB 300. The positioning mechanism 20 is fixed on the base 200 for preventing the carrying mechanism 10 from moving along a first direction.

The positioning mechanism 20 includes two positioning members 21 and a bottom plate 22. The positioning members 21 are facing each other and spaced a predetermined distance apart. The positioning member 21 is substantially U-shaped. The positioning member 21 further includes a first blocking plate 211, a second blocking plate 212, and a third blocking plate 213. The first blocking plate 211, the second blocking plate 212, and the third blocking plate 213 are substantially rectangular. The second blocking plate 212 and the third blocking plate 213 perpendicularly protrude from two opposite ends of the first blocking plate 211 away from the first blocking plate 211. Each of the blocking plate 211, the second blocking plate 212, and the third blocking plate 213 defines an inner surface 214, an outer surface 215 opposite to the inner surface 214, an upper surface 216, and a lower surface 217. The positioning member 21 further includes a resisting portion 218. The resisting portion 218 is substantially U-shaped. The resisting portion 218 is perpendicularly extended from the upper surface 216 of the first blocking plate 211, the second blocking plate 212, and the third blocking plate 213 away from to the lower surface 217 of the first blocking plate 211, the second blocking plate 212, and the third blocking plate 213. The resisting portion 218 respectively cooperates with the first blocking plate 211, the second blocking plate 212, and the third blocking plate 213. The positioning member 21 further defines a first through hole 219. The first through hole 219 goes through the first blocking plate 211 and is adjacent to the resisting portion 218. The resisting portions 218 cooperate with the first blocking plate 211, the second blocking plate 212, and the third blocking plate 213 to form a limiting region.

The bottom plate 22 is substantially rectangular. The bottom plate 22 defines a plurality of second through holes 221 and a plurality of first slits 222. The second through holes 221 correspond to the first through hole 219 in a one-to-one relationship. The second through hole 221 cooperates with the corresponding first through hole 219 for fixing the positioning member 21 on the bottom plate 22.

The carrying mechanism 10 mounted on the positioning mechanism 20 is located in the limiting region. The carrying mechanism 10 includes a loading member 11, a cover plate 12, a magnetic member 13, and a connecting member 14. The loading member 11 is used for receiving the PCB 300 and preventing the PCB form moving along the first direction. The cover plate 12 covers the PCB 300 and cooperates with the magnetic member 13 for tightly receiving in the loading member 11. The cover plate 12 is connected to the loading member 11 through the connecting member 14.

The loading member 11 is substantially rectangular. The loading member 11 defines a recess 113 in the middle of the loading member 11. The recess 113 is depressed from an upper surface of the loading member 11. The recess 113 defines a plurality of slits 1133. The slit 1133 goes through the loading member 11 and communicates with the recess 113. The loading member 11 includes two opposite first pressing portions 114 and two first retaining portions 115. The first pressing portions 114 are adjacent to the recess 113. The first pressing portion 114 defines a plurality of first grooves 1141 and a plurality of first blind holes 1142. The first grooves 1141 are parallel with each other. The first blind hole 1142 is arranged between the two adjacent first grooves 1141. The first retaining portions 115 are arranged at opposite ends of the loading member 11 and are adjacent to the first pressing portion 114 respectively.

The cover plate 12 is rotatably located on the loading member 11. The cover plate 12 is substantially rectangular. The cover plate 12 defines opening 123, and two second pressing portions 124, and two second retaining portions 125. The opening 123 corresponds to the recess 113. The opening 123 further includes a rod 1231. The rod 1231 connects two sidewalls of the opening 123. The second pressing portion 124 corresponding to the first pressing portion 114 is located at two opposite sidewalls of the opening 123. The second pressing portion 124 defines a plurality of second grooves 1241 and a plurality of second blind holes 1242. The second grooves 1241 are parallel with each other and correspond to the first grooves 114 respectively. The second blind hole 1242 is located between the two adjacent second grooves 1241. The second retaining portions 125 corresponding to the first retaining portion 125 are located at opposite ends of the cover plate 12 and are adjacent to the second pressing portion 124 respectively.

The magnetic member 13 includes a plurality of first magnetic portion 131 and a plurality of second magnetic portion 132 corresponding to the first magnetic portion 131 in a one-to-one relationship. The first magnetic portions 131 are received in the first blind holes 1142, and the second magnetic portions 132 are received in the second blind holes 1242. Each of the first magnetic portions 131 cooperates with the corresponding second magnetic portions 132 for preventing the PCB 300 from being moved along a second direction perpendicular to the first direction.

The connecting member 14 includes a first connection portion 141 and a second connection portion 142. The first connection portion 141 is fixed to the first retaining portion 115, and the second connection portion 142 is fixed to the second retaining portion 125. In one embodiment, the connecting member 14 is a hinge.

The base 200 defines a plurality of fixing holes 201. The fixing holes 201 correspond to the third slits 222 in a one-to-one relationship. Each of the fixing holes 201 cooperates with the corresponding third slit 222 for fixing the carrying mechanism 10 on the base 200.

The PCB 300 is substantially rectangular. The PCB 300 includes a top surface 301 and a bottom surface 302 opposite to the top surface 301. The PCB 300 further includes a plurality of electronic components 303 and a plurality of flat cables 304 which are mounted on the top surface 301 or the bottom surface 302. The flat cables are parallel with the top surface 301 and are extended away from the PCB 300.

In assembly, the positioning member 21 is fixed on the bottom plate 22. The loading member 11 is contacted with the resisting portions 218 for being received in the limiting region formed by the resisting portions 218. The PCB 300 is received in the recess 113. The top surface 301 of the PCB 300 is substantially coplanar with the loading member 11. The electronic components 303 on the bottom surface 302 are inserted into the corresponding slits 1133 and are exposed from the loading member 11. The flat cable 304 is partly received in the corresponding first grooves 1141. The cover plate 12 is rotatably connected to the loading member 11 through the connecting member 14. The cover plate 12 is manually rotated to cover the loading member 11. The flat cable 304 is partly received in the second grooves 1241. The first magnetic portion 131 and the second magnetic portions 132 attract each other for tightly contacting the cover plate 12 to the loading member 11. The electronic components 303 on the top surface 301 are inserted into the opening 123 and are exposed from the cover plate 12. The PCB 300 is prevented from moving along the second direction.

As described, the carrying mechanism 10 is capable of detaching from the positioning mechanism 20 for matching with different sizes of PCB 300. Therefore, the carrying apparatus 100 is capable of receiving different sizes of PCB 300.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A carrying apparatus fixed on a base for carrying a printed circuit board (PCB), the carrying apparatus comprising:
a carrying mechanism for receiving the PCB;
a positioning mechanism mounted on the base; and
wherein the carrying mechanism is received in the positioning mechanism and is capable of detaching from the positioning mechanism.

2. The carrying apparatus of claim 1, wherein the carrying mechanism comprises a loading member for receiving the PCB; the positioning mechanism comprises two opposite positioning members mounted on the base; the positioning member are distanced from each other; and two opposite ends of the loading member are contacted with the two opposite positioning members respectively.

3. The carrying apparatus of claim 2, wherein the carrying mechanism further comprises a cover plate; the loading member defines a recess; the PCB is received in the recess and prevents from moving along a first direction; the cover plate is rotatably connected to the loading member; and the cover plate cooperates the loading member for preventing the PCB from moving along a second direction which is perpendicular to the first direction.

4. The carrying apparatus of claim 3, wherein the PCB comprises a plurality of flat cables; the loading member further defines a plurality of first grooves; the cover plate defines a plurality of second grooves corresponding to the first grooves in a one-to-one relationship; and the flat cables are wholly received in one of the first grooves and the corresponding second groove respectively.

5. The carrying apparatus of claim 4, wherein the carrying mechanism further comprises a plurality of first magnetic portions and a plurality of second magnetic portions; the loading member further defines a plurality of first blind holes; the cover further defines a plurality of second blind holes corresponding to the first blind holes in a one-to-one relationship; the first magnetic portions are received in the first blind holes respectively, and the second magnetic portions are received in the second blind holes respectively; and when the cover is covered on the loading member, the first magnetic portion and the corresponding second magnetic attract with each other for making the cover plate tightly covered on the loading member.

6. The carrying apparatus of claim 5, wherein the blind holes are located between two adjacent grooves.

7. The carrying apparatus of claim 3, wherein the PCB comprises a plurality of electronic components soldered on the PCB; the recess defines a plurality of slits;
and when the PCB is received in the recess, the electronic components received in the recess is exposed from the loading member through the slits.

8. The carrying apparatus of claim 3, wherein the PCB comprises a plurality of electronic components soldered on the PCB; the cover plate further comprises an opening; and each of the electronic components facing the cover plate is partly exposed from the cover plate through the opening.

9. The carrying apparatus of claim 1, wherein the positioning member defines comprises a resisting portion; the resisting portion is substantially U-shaped; and
the carrying mechanism is contacted with the resisting portions for preventing the carrying mechanism from being moving along the first direction.

10. The carrying apparatus of claim 9, wherein the positioning member comprises a first block plate, a second block plate, and a third block plate; the second blocking plate and the third blocking plate are perpendicularly protruded from two opposite ends of the first blocking plate away from the first blocking plate; and the resisting portion is depressed from the first blocking plate and the second blocking plate, and the third blocking plate.

11. A carrying apparatus fixed on a base for carrying a printed circuit board (PCB), the carrying apparatus comprising:
a positioning mechanism mounted on the base; and
a carrying mechanism received in the positioning mechanism for receiving the PCB comprising:
a loading member defined a recess; and
a cover plate rotatably connected to the loading member;
wherein the carrying mechanism is capable of detaching from the positioning mechanism; the PCB is received in the recess and prevents from moving along a first direction; and the cover plate covered on the loading member for preventing the PCB from moving along a second direction which is perpendicular to the first direction.

12. The carrying apparatus of claim 11, wherein the positioning mechanism comprises two opposite positioning members mounted on the base; the positioning member are distanced from each other; and two opposite ends of the loading member are contacted with the two opposite positioning members respectively.

13. The carrying apparatus of claim 11, wherein the PCB comprises a plurality of flat cables; the loading member further defines a plurality of first grooves; the cover plate defines a plurality of second grooves corresponding to the first grooves in a one-to-one relationship; and the flat cables are wholly received in one of the first grooves and the corresponding second groove respectively.

14. The carrying apparatus of claim 11, wherein the carrying mechanism further comprises a plurality of first magnetic portions and a plurality of second magnetic portions; the loading member further defines a plurality of first blind holes; the cover further defines a plurality of second blind holes corresponding to the first blind holes in a one-to-one relationship; the first magnetic portions are received in the first blind holes respectively, and the second magnetic portions are received in the second blind holes respectively; and when the cover is covered on the loading member, the first magnetic portion and the corresponding second magnetic attract with each other for making the cover plate tightly covered on the loading member.

15. The carrying apparatus of claim 11, wherein the PCB comprises a plurality of electronic components soldered on the PCB; the recess defines a plurality of slits;
and when the PCB is received in the recess, the electronic components received in the recess is exposed from the loading member through the slits.

16. The carrying apparatus of claim 11, wherein the PCB comprises a plurality of electronic components soldered on the PCB; the cover plate further comprises an opening; and each of the electronic components facing the cover plate is partly exposed from the cover plate through the opening.

17. The carrying apparatus of claim 12, wherein the positioning member defines comprises a resisting portion; the resisting portion is substantially U-shaped; and
the carrying mechanism is contacted with the resisting portions for preventing the carrying mechanism from being moving along the first direction.

18. The carrying apparatus of claim 17, wherein the positioning member comprises a first block plate, a second block plate, and a third block plate; the second blocking plate and the third blocking plate are perpendicularly protruded from two opposite ends of the first blocking plate away from the first blocking plate; and the resisting portion is depressed from the first blocking plate and the second blocking plate, and the third blocking plate.
